(19) United States
(12) Patent Application Publication
(10) Pub. No.: US 2026/0320237 A1
(43) Pub. Date: Oct. 15, 2026

(54) SIMULATION METHOD AND APPARATUS FOR ELECTRONIC DEVICE CONTROL SYSTEM, DEVICE AND STORAGE MEDIUM

(71) Applicant: Shanghai Formal-Tech Information Technology Co., Ltd, Shanghai (CN)

(72) Inventors: Jianqi SHI, Shanghai (CN); Yanhong HUANG, Shanghai (CN); Sihui XIAO, Shanghai (CN)

(73) Assignee: Shanghai Formal-Tech Information Technology Co., Ltd, Shanghai (CN)

(21) Appl. No.: 19/482,508

(22) PCT Filed: Apr. 10, 2024
(86) PCT No.: PCT/CN2024/087030

§ 371 Date: Nov. 7, 2025

(30) Foreign Application Priority Data
May 8, 2023 (CN) 202310514199.9

(51) Int. Cl. G06F 30/12

(52) U.S. Cl. CPC G06F 30/12

(57) ABSTRACT

A simulation method and apparatus for an electronic device control system, a device and a storage medium. A target electronic device control system is analyzed to determine operation elements of the target electronic device control system. On the basis of the operation elements of the target electronic device control system, a target electronic device control system SysML model is constructed. According to a preset model conversion method, the target electronic device control system SysML model is converted into a target electronic device control system Simulink model. On the basis of the target electronic device control system Simulink model, the target electronic device control system is simulated. A mapping mode of the operation elements of the SysML model and the Simulink model can be determined to convert the target system SysML model into the target system Simulink model, such that the SysML model can reuse the Simulink tool.

### TECHNICAL FIELD

The present application relates to the field of computer simulation technologies, and more specifically, to a simulation method and apparatus for an electronic device control system, a device, and a storage medium.

### BACKGROUND

SysML is a graphical modeling language widely adopted in industry for modeling and designing complex systems, encompassing both functional and non-functional aspects. SysML reuses the relatively mature semantics and notations of UML 2.0, extending it to eliminate differences in expressions and terminology among different methods.

Although some software supports simulation for SysML models, its capabilities remain limited compared to specialized simulation software in the domains of continuous dynamic behavior modeling and discrete state behavior modeling. Simulink, as a powerful simulation tool, addresses these limitations by providing support for modeling, simulation, and analysis of dynamic systems within an interactive and graphical interface.

However, there is currently a lack of methods for electronic device control system simulation that are based on converting SysML models to Simulink models. To enable the SysML model to reuse the simulation and analysis capabilities of the Simulink tool, it is necessary to propose a method for converting a SysML model into a Simulink model. This allows the powerful simulation capability of the Simulink tool to be utilized to analyze the reliability and safety of embedded software. thus achieving improved simulation and analysis outcomes for the electronic device control system.

### SUMMARY

The present application addresses the lack of a conversion solution from a SysML model to a Simulink model.

To address the above issue, a first aspect of the present application provides a simulation method for an electronic device control system. The simulation method includes:
analyzing a target electronic device control system to determine operational elements thereof;
constructing a SysML model of the target electronic device control system based on the operational elements thereof;
converting the SysML model of the target electronic device control system into a Simulink model thereof according to a preset model conversion method; and
simulating the target electronic device control system based on the Simulink model thereof.

A second aspect of the present application provides a simulation apparatus for an electronic device control system. The simulation apparatus includes:
a system analysis module, configured to analyze a target electronic device control system and determine operational elements thereof;
a model construction module, configured to construct a SysML model of the target electronic device control system based on the operational elements thereof;
a model conversion module, configured to convert the SysML model of the target electronic device control system into a Simulink model thereof according to a preset model conversion method; and
a system simulation module, configured to simulate the target electronic device control system based on the Simulink model thereof.

A third aspect of the present application provides a terminal device. The terminal device includes: a memory and a processor.

The memory is configured to store a program.

The processor is coupled to the memory and configured to execute the program to implement the model conversion method described above or to implement the simulation method described above.

A fourth aspect of the present application provides a computer-readable storage medium having a computer program stored thereon. The program is executed by a processor to implement the model conversion method described above or the simulation method described above.

In the present application, after constructing a SysML model, the SysML model is converted into a Simulink model for simulation. This approach not only retains the generality advantage of the SysML model but also leverages the Simulink model to achieve superior simulation. By determining a mapping method of operational elements between the SysML model and the Simulink model, the target system SysML model is converted into the target system Simulink model. This enables the SysML model to reuse the Simulink tool, achieving better simulation and analysis effects for the electronic device control system.

### BRIEF DESCRIPTION OF THE DRAWINGS

FIG. 1 is a classification diagram of SysML model diagrams;

FIG. 2 is a flowchart of a model conversion method according to an embodiment of the present application;

FIG. 3 is a state machine diagram of a SysML model of a target electronic device control system according to the present application;

FIG. 4 is a stateflow diagram of a Simulink model of a target electronic device control system according to the present application;

FIG. 5 is a flowchart of a simulation method according to an embodiment of the present application;

FIG. 6 is a structural block diagram of a model conversion apparatus according to an embodiment of the present application;

FIG. 7 is a structural block diagram of a simulation apparatus according to an embodiment of the present application; and

FIG. 8 is a structural block diagram of a terminal device according to an embodiment of the present application.

### DETAILED DESCRIPTION

To make the above objectives, features, and advantages of the present application more apparent and easier to understand, detailed descriptions of specific embodiments of the present application are provided below with reference to the accompanying drawings. Although the exemplary embodiments of the present application are shown in the accompanying drawings, it should be understood that the present application can be implemented in various forms and should not be limited to the embodiments described herein. Rather, these embodiments are provided to enable a more thorough understanding of the present application and to fully convey the scope thereof to those skilled in the art.

It should be noted that, unless otherwise specified, technical terms or scientific terms used in the present application should have their commonly understood meanings as interpreted by those skilled in the art to which the present application belongs.

SysML is a widely used and expressive graphical modeling language that visualizes key aspects of system design—structure, behavior, requirements, and parameters (mathematical models)—thereby facilitating communication about the design. It was developed by the Object Management Group (OMG) and the International Council on Systems Engineering (INCOSE) to meet the modeling needs of the systems engineering filed by reusing and extending a subset of UML 2.0.

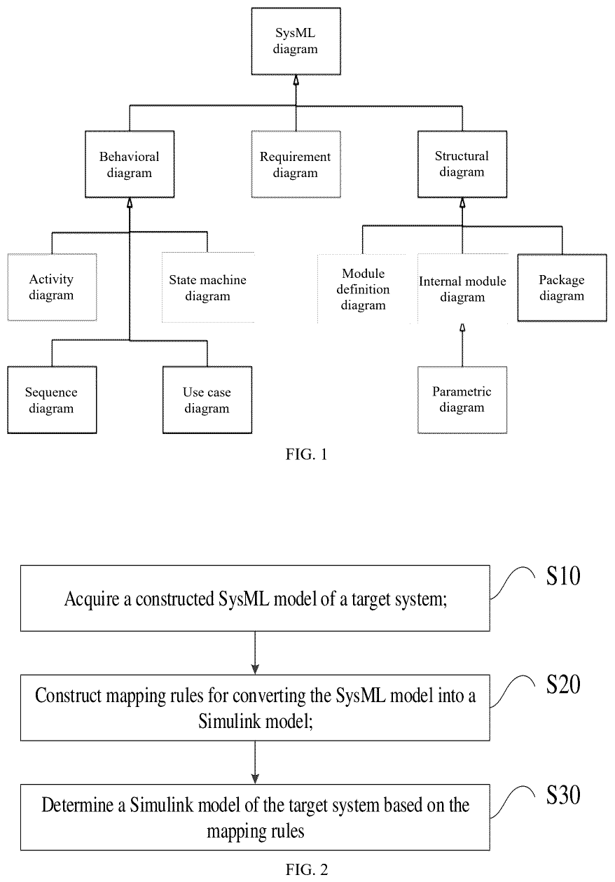

SysML diagrams are categorized into three types and nine kinds, as shown in FIG. 1. The three types are behavioral diagrams, requirement diagrams, and structural diagrams. These are further divided into nine specific model diagrams: activity diagrams, state machine diagrams, sequence diagrams, use case diagrams, requirement diagrams, module definition diagrams, internal module diagrams, package diagrams, and parametric diagrams. Among these, the diagram models for activity diagrams, module definition diagrams, and internal module diagrams are improved based on UML 2.0; while requirement diagrams and parametric diagrams are new diagram models in SysML.

Although some software supports simulation for SysML models, its capabilities remain limited compared to specialized simulation software in the domains of continuous dynamic behavior modeling and discrete state behavior modeling.

Simulink is a powerful visual simulation tool, providing a module diagram environment for multi-domain simulation and model-based design. Simulink supports modeling, simulation, and analysis of dynamic systems within an interactive, graphical interface and demonstrates excellent simulation effects in continuous dynamic behavior modeling and discrete state behavior modeling, thereby addressing the limitations of SysML.

Currently, there is a method for independently constructing a SysML model of the target system and a method for independently constructing a Simulink model of the target system. However, to leverage Simulink's powerful simulation capabilities for analyzing the reliability and safety of embedded software, the SysML model must be converted into a Simulink model. At present, there is a lack of a method to accomplish this conversion.

To address the above issue, the present application provides a new model conversion solution. This solution converts the SysML model of the target system into a Simulink model by establishing a mapping between the elements of the SysML model and the Simulink model.

The embodiments of the present application provide a model conversion method. The method may be executed by a model conversion apparatus, which can be integrated in an electronic device, such as a computer, a server, or a computing device.

FIG. 2 is a flowchart of a model conversion method according to an embodiment of the present application. The model conversion method includes the following steps.

In S10, a constructed SysML model of a target system is acquired.

The target system may be a target electronic device control system, for example, a flight control system or a driving control system of a smart vehicle.

For ease of understanding, the present application uses a target electronic device control system as an example to describe the specific application of the model conversion method thereto.

Acquiring the constructed SysML model of the target system may involve directly reading a preset SysML model of the target system; acquiring functional requirements of the target system and then constructing the SysML model based thereon; or other acquisition methods.

In S20, mapping rules for converting the SysML model into a Simulink model are constructed.

Both the SysML model and the Simulink model have defined operational elements. Some of the operational elements in the two models have corresponding conversion relationships. By analyzing the operational elements of the SysML model and the Simulink model, the corresponding mapping rules can be obtained/constructed.

In the target electronic device control system, the functional requirements of the target electronic device control system are fixed and unchanging. Therefore, some operational elements of the SysML model of the target electronic device control system are inevitably associated with the operational elements of the Simulink model of the target electronic device control system. By analyzing this association, the mapping rules between the two models can be obtained/constructed.

For example, when the electronic device control system switches from a cooling state to a heating state under the control of a controller, an association must exist between the corresponding operational elements in the SysML model and those in the Simulink model.

In S30, a Simulink model of the target system is determined based on the mapping rules.

Based on the mapping rules, (some of) the operational elements of the SysML model of the target system are mapped to the operational elements of the Simulink model of the target system, and the Simulink model of the target system is constructed/determined based on the operational elements.

In the target electronic device control system, the operational elements of the SysML model of the target electronic device control system are converted into the operational elements of the Simulink model of the target electronic device control system according to the mapping rules, and the Simulink model of the target electronic device control system is constructed/determined based on the operational elements.

In this way, by determining a mapping method of operational elements between the SysML model and the Simulink model, the SysML model of the target system/target electronic device control system is converted into the Simulink model of the target system/target electronic device control system. This enables the SysML model to reuse the Simulink tool, thereby achieving superior simulation and analytical outcomes.

By reusing the Simulink tool, tools like Design Verify can be used to validate the modeling of complex systems, thereby effectively ensuring the correctness of the established SysML model of the target system.

In one embodiment, the SysML model comprises a state machine diagram, and the Simulink model comprises a stateflow diagram.

In the mapping rules for converting the SysML model into the Simulink model, the state machine diagram of the SysML model is mapped to the stateflow diagram of the Simulink model.

Specifically, the state machine diagram in a SysML model is a type of behavioral diagram that illustrates the dynamic behavior of a system, focusing on how the system changes its state over time in response to events. It provides a precise and explicit behavioral specification, typically used for system design and simulation in the SysML model.

Stateflow (the stateflow diagram) is a module in Simulink for creating finite state machines. It models and simulates decision logic by using state machines and flowcharts.

In this way, simply mapping the state machine diagram of the SysML model to the stateflow diagram of the Simulink model allows for the reuse of the simulation tool and effects of the Simulink model.

It should be noted that Stateflow is directly embedded into the Simulink model. During the initialization phase of simulation, Simulink converts the logical graphics in Stateflow into C code via a compilation process to perform simulation. The specific compilation process may involve minor adjustments depending on the target system, simulation tools, etc. The present application does not restrict these specific adjustments or the specific compilation process.

It should be noted that the Simulink model includes not only Stateflow but also a state conversion diagram, a flowchart, among others. However, during the specific simulation process, only Stateflow can be compiled into C code. The state conversion diagrams and flowcharts serve as supplementary details within the simulation process, contributing to enhanced clarity and overall simulation fidelity.

In an embodiment, the state machine diagram includes an input variable, a local variable, and an output variable, and the stateflow diagram includes input data, local data, and output data.

Mapping the state machine diagram of the SysML model to the stateflow diagram of the Simulink model includes:
mapping the input variable of the state machine diagram to the input data of the stateflow diagram;
mapping the local variable of the state machine diagram to the local data of the stateflow diagram; and
mapping the output variable of the state machine diagram to the output data of the stateflow diagram.

The state machine diagram (STM) includes input variables, local variables, and output variables. The Simulink model/stateflow diagram includes input data (Input Data), local data (Local Data), and output data (Output Data).

It should be noted that the input data (Input Data), local data (Local Data), and output data (Output Data) included in the Simulink model and the stateflow diagram are the same data. Therefore, such data can be considered as variable data of the Simulink model or as variable data of the stateflow diagram.

In an embodiment, the state machine diagram further includes a simple state, a state transition, and a composite state. The state transition includes a trigger element, a guard element, and an effect element. The stateflow diagram includes a state element, a transition element, and a chart block element. The transition element includes a transition event, a transition guard, and a transition effect.

Mapping the state machine diagram of the SysML model to the stateflow diagram of the Simulink model further includes:
mapping the simple state of the state machine diagram to the state element of the stateflow diagram;
mapping the state transition of the state machine diagram to the transition element of the stateflow diagram; and
mapping the composite state of the state machine diagram to the chart block element of the stateflow diagram.

In mapping the state transition of the state machine diagram to the transition element of the stateflow diagram, the trigger element, the guard element, and the effect element of the state transition are respectively mapped to the transition event, the transition guard, and the transition effect of the transition element.

The state machine diagram further includes simple states (state), a state transition (transition), and composite states (composite state). A state transition includes a trigger element (trigger), a guard element (guard), and an effect element (effect). The stateflow diagram includes state elements (state), transition elements (transition), and chart block elements (chart). A transition element includes a transition event (Event), a transition guard (Guard), and a transition effect (Effect).

The state machine diagram primarily includes the following elements:
Simple State (state): Its description includes state names, entry and exit actions, internal activities, internal transitions, etc.
Composite State (composite state): A state that includes nested substates, also known as a combined state.
State Transition (transition): A relationship between two states; the state transition includes a trigger element (trigger), a guard element (guard), and an effect element (effect):
Trigger Element (trigger): A phenomenon that acts externally on one object and can trigger a state change in the object.
Guard Element (guard): A Boolean expression that serves as the condition that must be satisfied to trigger the state transition.
Effect Element (effect): Behaviors executed when the state transition is activated. In other words, when the transition is triggered, if a corresponding action is defined, that action is executed.

Stateflow primarily includes the following elements:
State Element (state): Describes a mode of system operation with Boolean behavior. At any given time, a state is either active or inactive. Internally, a state is further divided into: entry (an entry action for specifying the action that occurs when entering the state and typically used for the internal initialization required by the state); doing (an internal activity for specifying the activity that is continuously performed while in a given state; the internal activity persists until interrupted by the arrival of an external event, or until the activity is completed, the state is finished, and a transition is triggered); and exit (an exit action for specifying the action that occurs when leaving the state and typically used to represent the processing task that need to be performed upon exiting a state).
Transition Element (transition): A transition connects two states. When a transition occurs, the target state becomes active, and the source state becomes inactive.
Default Transition (default transition): The default transition is a special type of transition used to specify the state machine at the current hierarchical level.
Chart Block Element (chart): A chart block element is a nested Stateflow model that can include all Stateflow elements.

In the present application, by analyzing the SysML state machine diagram model and the Simulink model, mapping rules from the SysML state machine diagram to the Simulink model are established. The State in the state machine diagram is converted to Stateflow in the Simulink model; the Transition in the state machine diagram is converted to Transition in the Simulink model; the Composite State in the state machine diagram is converted to Chart in the Simulink model. The Trigger, Condition, and Effect on the Transition in the SysML state machine diagram are respectively converted into the Event, Guard, and Effect on the Transition in the Simulink model.

It should be noted here that the English names of elements in the state machine diagram and the English names of elements in Stateflow are the common names in the corresponding models. Some elements share identical English names (such as Transition, State, Effect) due to their similar meanings/functions. However, these elements essentially belong to different models and should not be regarded as completely identical in meaning.

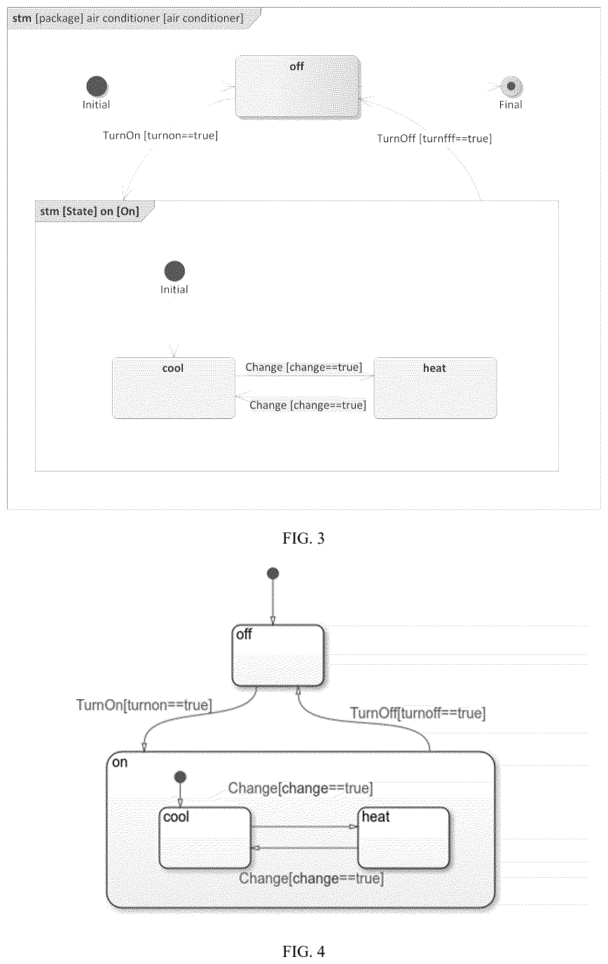

As shown in FIG. 3, combined with FIG. 4, in the target electronic device control system, the state machine diagram defines four states: an off state (off), an operating state (on), a cooling state (cool), and a heating state (heat). Among these, the off state (off), the cooling state (cool), and the heating state (heat) are simple states; the operating state (on) is a composite state, which includes the cooling state (cool) and the heating state (heat) (indicating that under the operating state, the electronic device control system is further divided into two situations: the heating state and the cooling state).

The cooling state (cool) and the heating state (heat) are both simple states and also substates of the composite operating state (on).

In the target electronic device control system, two state transitions connect the off state (off) and the operating state (on), indicating that the electronic device control system switches between the off and operating states. Within the operating state (on), the cooling state (cool) and the heating state (heat) are connected via a state transition, indicating that the electronic device control system can switch between cooling and heating while in the operating state.

In the target electronic device control system, the state machine diagram includes three trigger elements: TurnOn, TurnOff, and Change.

It should be noted that the state machine diagram includes only three trigger elements: TurnOn, TurnOff, and Change. It can be considered that the state machine diagram does not include guard elements and effect elements, or it can also be considered that the corresponding guard elements in the state machine diagram are TurnOn=true, TurnOff=true, and Change=true.

In the target electronic device control system, the state machine diagram includes three input variables: TurnOn, TurnOff, and Change.

In an embodiment, determining the Simulink model of the target system based on the mapping rules includes: mapping the operational elements of the SysML model of the target electronic device control system to the operational elements of the Simulink model of the target electronic device control system based on the mapping rules, and constructing the Simulink model of the target electronic device control system using the mapped operational elements of the Simulink model of the target electronic device control system.

In an embodiment, said mapping of the operational elements includes:
mapping the three input variables of the state machine diagram—TurnOn, TurnOff, and Change—to the three input data of the stateflow diagram.

The three input data of the mapped stateflow diagram are TurnOn, TurnOff, and Change.

The mapping rules include the mapping rules for input variables, local variables, and output variables. When the state machine diagram includes only input variables, only the input variables of the state machine diagram are mapped to the input data of the stateflow diagram.

Similarly, when the state machine diagram includes only one or two types of variables among input variables, local variables, and output variables, only the variables included in the state machine diagram are mapped to the data of the stateflow diagram.

Similarly, it is not necessary for the trigger element (trigger), the guard element (guard), and the effect element (effect) in the state transition to all be present.

In an embodiment, mapping the operational elements of the SysML model of the target electronic device control system to the operational elements of the Simulink model of the target electronic device control system further includes:
mapping an off state (off), a cooling state (cool), and a heating state (heat) of the state machine diagram to an off state element (off), a cooling state element (cool), and a heating state element (heat) of the stateflow diagram, respectively;
mapping an operating state (on) of the state machine diagram to an operating state chart block (on) of the stateflow diagram; and
mapping trigger elements in a state transition of the state machine diagram—TurnOn, TurnOff, and Change—to transition events (Event) of transition elements in the stateflow diagram: TurnOn, TurnOff, and Change.

The three transition events (Event) of the transition elements of the mapped stateflow diagram are: TurnOn, TurnOff, and Change.

Thus, through the three input data of the mapped stateflow diagram—TurnOn, TurnOff, and Change—the off state element (off), the cooling state element (cool), the heating state element (heat), the operating state chart block (on), and the three transition events (Event) of the transition elements: TurnOn, TurnOff, and Change, the Simulink model of the target electronic device control system is constructed.

The specific process for constructing the Simulink model of the target electronic device control system using the operational elements of the Simulink model will not be further elaborated in the present application.

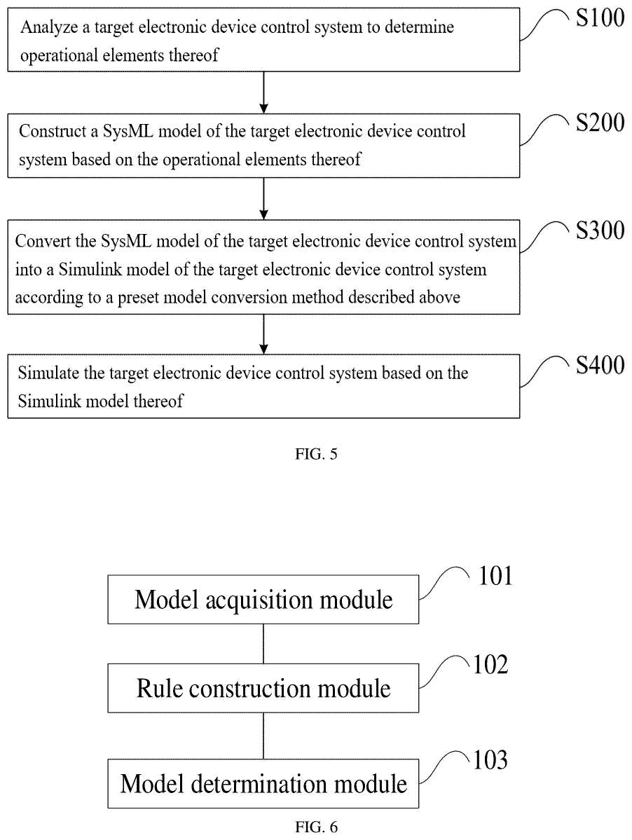

The embodiments of the present application provide a simulation method for an electronic device control system. The method can be executed by a simulation apparatus, which can be integrated into an electronic device such as a computer, a server, or a computing device. FIG. 5 is a flowchart of a simulation method according to an embodiment of the present application. The simulation method includes the following steps.

In S100, a target electronic device control system is analyzed to determine operational elements thereof.

In an embodiment, the operational elements of the target electronic device control system include:
an initial state of an electronic device control system being in an off state;
the electronic device control system entering an operating state when the electronic device control system is turned on using a remote control;
the electronic device control system entering the off state when the electronic device control system is turned off using a remote control;
in the operating state, the electronic device control system, by default, being in a cooling state; and
the electronic device control system switching between the cooling state and a heating state when the remote control is used to change a state of the electronic device control system.

It should be noted that the operational elements of the target electronic device control system are determined based on the analysis of the target electronic device control system. The electronic device control system is a system frequently used in practical applications. The present application only focuses on the target electronic device control system, and other forms of electronic device control systems are not elaborated herein.

In S200, a SysML model of the target electronic device control system is constructed based on the operational elements.

Based on the operational elements of the target electronic device control system, the SysML modeling language is used to construct a requirement diagram, a use case diagram, a module definition diagram, and a state machine diagram for the target electronic device control system.

The requirement diagram includes an electronic device control system architecture and electronic device control system functionality. The electronic device control system architecture may include a control layer and an execution layer. The control layer primarily includes an electronic device control system controller, which is configured to determine a control instruction. The execution layer includes a switch and a cooling/heating switching unit, which are configured to execute the control instruction.

Based on the electronic device control system architecture, a module definition diagram is constructed: The system architecture is divided into two layers, so the module definition diagram is divided into two modules, namely a control module and an execution module. Each module includes a plurality of units.

Based on the usage scenario of the target electronic device control system, a use case diagram for the target electronic device control system is constructed. The specific construction process is not elaborated in the present application.

Based on the operational elements of the target electronic device control system, a state machine diagram for the target electronic device control system is constructed.

In the constructed state machine diagram, four states are defined: an off state (off), an operating state (on), a cooling state (cool), and a heating state (heat). Among these, the off state (off), the cooling state (cool), and the heating state (heat) are simple states; the operating state (on) is a composite state, which includes the cooling state (cool) and the heating state (heat) (indicating that under the operating state, the electronic device control system is further divided into two situations: the heating state and the cooling state).

The cooling state (cool) and the heating state (heat) are both simple states and also substates of the composite operating state (on).

In the constructed state machine diagram, the off state (off) and the operating state (on), are connected by two state transitions, enabling the system to switch between the off and operating states. Within the operating state (on), the cooling state (cool) and the heating state (heat) are connected via a state transition, indicating that the electronic device control system can switch between cooling and heating while in the operating state.

In the constructed state machine diagram, three trigger elements are included: TurnOn, TurnOff, and Change.

In the constructed state machine diagram, three input variables are included: TurnOn, TurnOff, and Change.

In S300, the SysML model of the target electronic device control system is converted into a Simulink model of the target electronic device control system according to the model conversion method described above.

The specific process of converting the SysML model of the target electronic device control system into the Simulink model of the target electronic device control system can be referred to in the model conversion method described in steps S10 to S30, and will not be further elaborated in this step.

In S400, the target electronic device control system is simulated based on the Simulink model of the target electronic device control system.

In this step, once the Simulink model of the target electronic device control system is finalized, simulation can be performed either by initializing and compiling into a C program or through the MATLAB command window. The specific simulation process will not be further elaborated here.

In this way, after constructing a SysML model, the SysML model is converted into a Simulink model for simulation. This approach not only retains the generality advantage of the SysML model but also leverages Simulink model for better simulation.

The embodiments of the present application provide a model conversion apparatus, which is configured to execute the model conversion method described above in the present application. A detailed description of the model conversion apparatus is provided hereinafter.

As shown in FIG. 6, the model conversion apparatus includes:
a model acquisition module 101, configured to acquire a constructed SysML model of a target system;
a rule construction module 102, configured to construct mapping rules for converting the SysML model into a Simulink model; and
a model determination module 103, configured to determine the Simulink model of the target system based on the mapping rules.

In an embodiment, the SysML model includes a state machine diagram, and the Simulink model includes a stateflow diagram (stateflow). In the mapping rules for converting the SysML model into the Simulink model, the state machine diagram of the SysML model is mapped to the stateflow diagram of the Simulink model.

In an embodiment, the state machine diagram includes input variables, local variables, and output variables, and the stateflow diagram includes input data, local data, and output data. The rule construction module 102 is further configured to:
map the input variables of the state machine diagram to the input data of the stateflow diagram; map the local variables of the state machine diagram to the local data of the stateflow diagram; and map the output variables of the state machine diagram to the output data of the stateflow diagram.

In an embodiment, the state machine diagram further includes a simple state, a state transition, and a composite state. The state transition includes a trigger element, a guard element, and an effect element. The stateflow diagram includes a state element, a transition element, and a chart block element. The transition element includes a transition event, a transition guard, and a transition effect.

The rule construction module 102 is further configured to:
map the simple state of the state machine diagram to the state element of the stateflow diagram; map the state transition of the state machine diagram to the transition element of the stateflow diagram; and map the composite state of the state machine diagram to the chart block element of the stateflow diagram, where in mapping the state transition of the state machine diagram to the transition element of the stateflow diagram, the trigger element, the guard element, and the effect element of the state transition are respectively mapped to the transition event, the transition guard, and the transition effect of the transition element.

The model conversion apparatus provided according to the above embodiments of the present application shares the same inventive concept as the model conversion method provided according to the embodiments of the present application and has the same beneficial effects as the method adopted, executed, or implemented by the application program stored in the apparatus.

The embodiments of the present application provide a simulation apparatus, configured to execute the simulation method described above in the present application. A detailed description of the simulation apparatus is provided hereinafter.

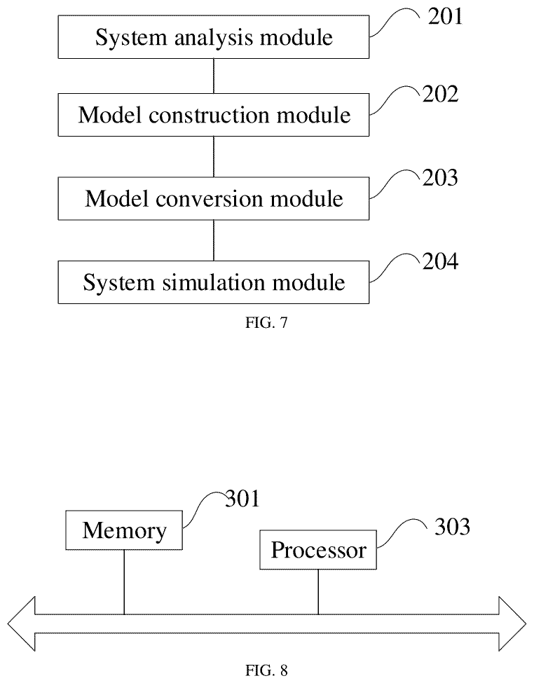

As shown in FIG. 7, the simulation apparatus includes:
a system analysis module 201, configured to analyze a target electronic device control system and determine operational elements of the target electronic device control system;
a model construction module 202, configured to construct a SysML model of the target electronic device control system based on the operational elements of the target electronic device control system;
a model conversion module 203, configured to convert the SysML model of the target electronic device control system into a Simulink model of the target electronic device control system according to the model conversion method described above; and
a system simulation module 204, configured to simulate the target electronic device control system based on the Simulink model of the target electronic device control system.

In an embodiment, the operational elements of the target electronic device control system include:
The initial state of the electronic device control system is in an off state; when the electronic device control system is turned on using a remote control, the electronic device control system enters an operating state; when the electronic device control system is turned off using the remote control, the electronic device control system enters an off state; in the operating state, the electronic device control system is by default in a cooling state; when the remote control is used to change the state of the electronic device control system, the electronic device control system switches between the cooling state and the heating state.

The simulation apparatus provided according to the above embodiments of the present application shares the same inventive concept as the simulation method provided according to the embodiments of the present application and has the same beneficial effects as the method adopted, executed, or implemented by the application program stored in the apparatus.

The internal functions and structures of the model conversion apparatus and the simulation apparatus are described above. As shown in FIG. 8, the model conversion apparatus and the simulation apparatus can be implemented as terminal devices in practice, including: a memory 301 and a processor 303.

The memory 301 may be configured to store a program.

In addition, the memory 301 may be configured to store various other types of data to support operations on the terminal device. Examples of such data include instructions for executing any applications or methods on the terminal device, contact data, telephone directory data, messages, pictures, videos, etc.

The memory 301 is implemented using any type of volatile or non-volatile storage device, or a combination thereof, such as Static Random Access Memory (SRAM), Electrically Erasable Programmable Read-Only Memory (EEPROM), Electrically Erasable Programmable Read-Only Memory (EPROM), Programmable Read-Only Memory (PROM), Read-Only Memory (ROM), magnetic memory, flash memory, magnetic disks, or optical disks.

The processor 303, coupled to the memory 301, is configured to execute the program stored in the memory 301 for:
acquiring a constructed SysML model of a target system;
constructing mapping rules for converting the SysML model into a Simulink model; and
determining a Simulink model of the target system based on the mapping rules.

Alternatively, the processor is configured to execute the program stored in the memory for:
analyzing a target electronic device control system to determine operational elements thereof;
constructing a SysML model of the target electronic device control system based on the operational elements of the target electronic device control system;
converting the SysML model of the target electronic device control system into a Simulink model of the target electronic device control system according to the model conversion method described above; and
simulating the target electronic device control system based on the Simulink model of the target electronic device control system.

In an embodiment, the SysML model includes a state machine diagram, and the Simulink model includes a stateflow diagram (stateflow). In the mapping rules for converting the SysML model into the Simulink model, the state machine diagram of the SysML model is mapped to the stateflow diagram of the Simulink model.

In an embodiment, the state machine diagram includes an input variable, a local variable, and an output variable, and the stateflow diagram includes input data, local data, and output data.

The processor 303 is specifically configured to:
map the input variable of the state machine diagram to the input data of the stateflow diagram; map the local variable of the state machine diagram to the local data of the stateflow diagram; and map the output variable of the state machine diagram to the output data of the stateflow diagram.

In an embodiment, the state machine diagram further includes a simple state, a state transition, and a composite state. The state transition includes a trigger element, a guard element, and an effect element. The stateflow diagram includes a state element, a transition element, and a chart block element. The transition element includes a transition event, a transition guard, and a transition effect.

The processor 303 is specifically configured to:
map the simple state of the state machine diagram to the state element of the stateflow diagram; map the state transition of the state machine diagram to the transition element of the stateflow diagram; and map the composite state of the state machine diagram to the chart block element of the stateflow diagram, where in mapping the state transition of the state machine diagram to the transition element of the stateflow diagram, the trigger element, the guard element, and the effect element of the state transition are respectively mapped to the transition event, the transition guard, and the transition effect of the transition element.

In an embodiment, the operational elements of the target electronic device control system include:
The initial state of the electronic device control system is in an off state; when the electronic device control system is turned on using a remote control, the electronic device control system enters an operating state; when the electronic device control system is turned off using the remote control, the electronic device control system enters an off state; in the operating state, the electronic device control system is by default in a cooling state; when the remote control is used to change the state of the electronic device control system, the electronic device control system switches between the cooling state and the heating state.

In the present application, FIG. 8 schematically illustrates only some components. This does not imply that the terminal device includes only the components shown in FIG. 8.

The terminal device provided according to the embodiment shares the same inventive concept as the model conversion method and the simulation method provided according to the embodiments of the present application and has the same beneficial effects as the method adopted, executed, or implemented by the application program stored in the terminal device.

Those skilled in the art should understand that the embodiments of the present application may be provided as a method, a system, or a computer program product. Accordingly, the present application may take the form of an entirely hardware embodiment, an entirely software embodiment, or an embodiment combining software and hardware. Furthermore, the present application may take the form of a computer program product implemented on one or more computer-readable storage media (including, but not limited to, disk memory, CD-ROM, optical memory, etc.) containing computer-usable program codes.

The present application is described with reference to flowcharts and/or block diagrams of the methods, the devices (systems), and the computer program products according to the embodiments of the present application. It should be understood that each flow and/or block of the flowcharts and/or block diagrams, and a combination of flows and/or blocks in the flowcharts and/or block diagrams, can be implemented by computer program instructions. These computer program instructions may be provided to a processor of a general-purpose computer, a dedicated computer, an embedded processor or other programmable data processing devices to produce a machine, such that the instructions executed by the processor of the computer or other programmable data processing devices produce an apparatus for implementing the functions specified in one or more flowchart flows and/or one or more blocks of block diagrams.

These computer program instructions may also be stored in a computer-readable memory that can direct a computer or other programmable data processing devices to operate in a particular manner, such that the instructions stored in the computer-readable memory produce a product an article of manufacture including instruction means that implements the functions specified in one or more flowchart flows and/or one or more blocks of block diagrams.

These computer program instructions may also be loaded onto a computer or other programmable data processing devices to allow a series of operation steps to be performed on the computer or other programmable devices to produce a computer-implemented process, such that the instructions executed on the computer or other programmable device provide steps for implementing the functions specified in one or more flowchart flows and/or one or more blocks of block diagrams.

In a typical configuration, a computing device includes one or more processors (CPUs), input/output interfaces, a network interface, and a memory.

The memory may include non-permanent memory within the computer-readable medium, in forms such as Random Access Memory (RAM), and/or non-volatile memory, such as Read-Only Memory (ROM) or flash memory (flash RAM), within the computer-readable medium. The memory is an example of a computer-readable medium.

The present application further provides a computer-readable storage medium corresponding to the model conversion method and the simulation method provided according to the foregoing embodiments. The computer-readable storage medium stores a computer program (i.e., program product) thereon. The computer program, when executed by a processor, performs the model conversion method provided according to any one of the foregoing embodiments or the simulation method provided according to any one of the foregoing embodiments.

The computer-readable medium includes permanent and non-permanent, removable and non-removable media, which can store information using any method or technology. The information may include computer-readable instructions, data structures, program modules, or other data. Examples of computer storage media include, but are not limited to, Phase-Change Memory (PRAM), Static Random Access Memory (SRAM), Dynamic Random Access Memory (DRAM), other types of Random Access Memory (RAM), Read-Only Memory (ROM), Electrically Erasable Programmable Read-Only Memory (EEPROM), flash memory, or other memory technologies; Compact Disc Read-Only Memory (CD-ROM), Digital Versatile Discs (DVD), or other optical storages; magnetic cassette tapes, magnetic tapes, magnetic disk storages, or other magnetic storage devices; or any other non-transmission medium that can be used to store information accessible by a computing device. As defined herein, the computer-readable medium does not include transitory computer-readable media, such as modulated data signals and carrier waves.

The computer-readable storage medium provided according to the above embodiments of the present application shares the same inventive concept as the model conversion method and the simulation method provided according to the embodiments of the present application and has the same beneficial effects as the method adopted, executed, or implemented by the application program stored in the computer-readable storage medium.

It should be noted that in the specification provided herein, a large number of specific details are described. However, it can be understood that the embodiments of the present application may be practiced without these specific details. In some instances, well-known structures and techniques are not shown in detail so as not to obscure the understanding of this specification.

It should also be noted that the terms “comprising”, “including”, or any other variations thereof are intended to cover a non-exclusive inclusion, such that a process, method, article, or device that includes a series of elements not only includes those elements but may also include other elements not explicitly listed or elements inherent to such process, method, article, or device. Without further limitations, an element defined by the phrase “comprising a/an . . . ” does not exclude the presence of additional identical elements in the process, method, article, or device including the stated element.

The above descriptions are merely embodiments of the present application, but are not intended to limit the present application. For those skilled in the art, the present application may have various modifications and variations. Any modifications, equivalent substitutions, improvements, etc., made within the spirit and principles of the present application shall fall within the scope of the claims of the present application.

1. A simulation method for an electronic device control system, comprising:
analyzing a target electronic device control system to determine operational elements thereof;
constructing a SysML model of the target electronic device control system based on the operational elements thereof;
converting the SysML model of the target electronic device control system into a Simulink model of the target electronic device control system according to a preset model conversion method; and
simulating the target electronic device control system based on the Simulink model thereof.

2. The method according to claim 1, wherein the operational elements of the target electronic device control system comprise:
an initial state of an electronic device control system being in an off state;
the electronic device control system entering an operating state when the electronic device control system is turned on using a remote control;
the electronic device control system entering the off state when the electronic device control system is turned off using a remote control;
in the operating state, the electronic device control system, by default, being in a cooling state; and
the electronic device control system switching between the cooling state and a heating state when the remote control is used to change a state of the electronic device control system.

3. The method according to claim 1, wherein the model conversion method comprises:
acquiring a constructed SysML model of a target system;
constructing mapping rules for converting the SysML model into a Simulink model; and
determining a Simulink model of the target system based on the mapping rules.

4. The method according to claim 3, wherein the SysML model comprises a state machine diagram, and the Simulink model comprises a stateflow diagram, wherein
in the mapping rules for converting the SysML model into the Simulink model, the state machine diagram of the SysML model is mapped to the stateflow diagram of the Simulink model.

5. The method according to claim 4, wherein the state machine diagram comprises an input variable, a local variable, and an output variable, and the stateflow diagram comprises input data, local data, and output data; and
mapping the state machine diagram of the SysML model to the stateflow diagram of the Simulink model comprises:
mapping the input variable of the state machine diagram to the input data of the stateflow diagram;
mapping the local variable of the state machine diagram to the local data of the stateflow diagram; and
mapping the output variable of the state machine diagram to the output data of the stateflow diagram.

6. The method according to claim 5, wherein the state machine diagram further comprises a simple state, a state transition, and a composite state, and the state transition comprises a trigger element, a guard element, and an effect element; the stateflow diagram comprises a state element, a transition element, and a chart block element, and the transition element comprises a transition event, a transition guard, and a transition effect; and
mapping the state machine diagram of the SysML model to the stateflow diagram of the Simulink model further comprises:
mapping the simple state of the state machine diagram to the state element of the stateflow diagram;
mapping the state transition of the state machine diagram to the transition element of the stateflow diagram; and
mapping the composite state of the state machine diagram to the chart block element of the stateflow diagram,
wherein in mapping the state transition of the state machine diagram to the transition element of the stateflow diagram, the trigger element, the guard element, and the effect element of the state transition are respectively mapped to the transition event, the transition guard, and the transition effect of the transition element.

7. A simulation apparatus for an electronic device control system, comprising:
a system analysis module, configured to analyze a target electronic device control system and determine operational elements thereof;
a model construction module, configured to construct a SysML model of the target electronic device control system based on the operational elements thereof;
a model conversion module, configured to convert the SysML model of the target electronic device control system into a Simulink model thereof according to a preset model conversion method; and
a system simulation module, configured to simulate the target electronic device control system based on the Simulink model thereof.

8. A terminal device, comprising: a memory and a processor, wherein
the memory is configured to store a program; and
the processor is coupled to the memory and configured to execute the program to implement the method according to claim 1.

9. A computer-readable storage medium, having a computer program stored thereon, wherein the program, when executed by a processor, causes the processor to implement the method according to claim 1.
